(19) United States
(12) Patent Application Publication
(10) Pub. No.: US 2026/0043167 A1
(43) Pub. Date: Feb. 12, 2026

(54) LARGE SINGLE-CRYSTAL PRUSSIAN WHITE-BASED SODIUM-ION POSITIVE ELECTRODE MATERIAL AND METHOD FOR PREPARING SAME

(71) Applicants: Guizhou Zhenhua E-CHEM Inc., Guiyang (CN); Guizhou Zhenhua E-CHEM Co., Ltd., Guiyang (CN); Guizhou Zhenhua Yilong E-CHEM Co., Ltd, Guizhou (CN)

(72) Inventors: Jin HUANG, Guiyang (CN); Xianjin WANG, Guiyang (CN); Ye YU, Guiyang (CN); Ansheng HU, Guiyang (CN); Yang WU, Guiyang (CN)

(21) Appl. No.: 19/297,147

(22) Filed: Aug. 12, 2025

(30) Foreign Application Priority Data
Aug. 12, 2024 (CN) 202411102185.7

(51) Int. Cl. C30B 7/14; C30B 29/10; H01M 10/054

(52) U.S. Cl. CPC C30B 7/14; C30B 29/10; H01M 10/054

(57) ABSTRACT

The present disclosure provides a large single-crystal Prussian white-based sodium-ion positive electrode material and a method for preparing same. The Prussian white-based sodium-ion positive electrode material has a chemical general formula NaₓMn[Fe(CN)₆], wherein 1.9≤x<2.00. The method comprises: (1) mixing and dissolving Na₄Fe(CN)₆·10H₂O and ethylenediaminetetraacetic acid manganese sodium salt to prepare a first solution A; and (2) dropwise adding a diluted acid, as a second solution B, into the first solution A, performing an aging reaction, washing, and drying to give the Prussian white-based sodium-ion positive electrode material with a low water content. By using an acidic cation dissociation method, the present disclosure synthesizes a Prussian white-based sodium-ion positive electrode material with a low water content at room temperature, and the synthesized material features large primary particles, good thermal stability, a low water content, and a high capacity.

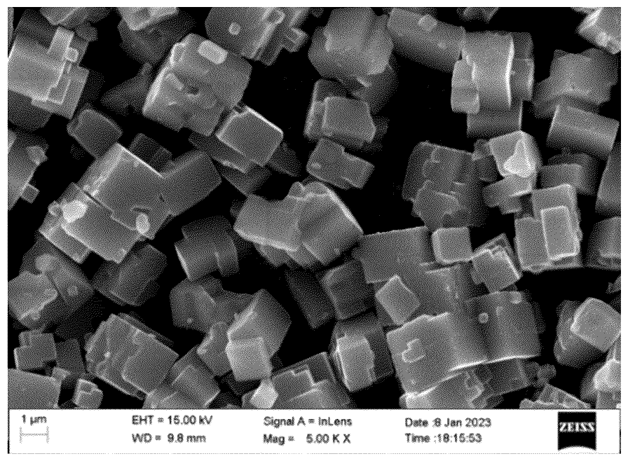

### TECHNICAL FIELD

The present disclosure relates to the field of sodium-ion battery technology, and in particular, to a large single-crystal Prussian white-based sodium-ion positive electrode material and a method for preparing same.

### BACKGROUND

As a “substitute” for lithium-ion batteries, sodium-ion batteries have attracted attention throughout the world. The electrode material used in sodium-ion batteries is primarily sodium salts, which feature abundant reserves and various sources and thus cost-efficiency compared with lithium salts. Due to the larger radius of the sodium ion compared with that of the lithium ion, sodium-ion batteries are a preferred alternative when the weight and energy density are not restricted. Prussian blue-based sodium-ion positive electrode materials are favorable in the art due to ease of preparation, various sources, and cost-efficiency.

Currently, Prussian white-based positive electrode materials are generally synthesized by adding dropwise a manganese or iron source solution into a Na₄Fe(CN)₆·10H₂O solution before reacting at a constant temperature of 40 to 60° C. for several hours. However, there is a risk of HCN production in thermal settings, and the difficulties in controlling the reaction rate during the reaction process impose the requirement for complexing agents. The Prussian white positive electrode materials synthesized by the conventional methods possess a high water content, as well as uneven precipitates of Na and Mn and an uncontrollable ratio thereof.

Therefore, more studies are required on the synthesis methods of Prussian white-based sodium-ion positive electrode materials.

### SUMMARY

To resolve the defects in the prior art, the present disclosure provides a large single-crystal Prussian white-based sodium-ion positive electrode material and a method for preparing same. The method enables the synthesis of the large single-crystal Prussian white-based sodium-ion positive electrode material at room temperature and more uniform precipitation of Na and Mn by preparing Na and a manganese source into a mixed solution.

Technical solution: Provided is a method for preparing a large single-crystal Prussian white-based sodium-ion positive electrode material, comprising:
step 1, mixing and dissolving Na₄Fe(CN)₆·10H₂O and ethylenediaminetetraacetic acid manganese sodium salt to prepare a first solution A; and
step 2, dropwise adding a diluted acid, as a second solution B, into the first solution A while stirring, performing an aging reaction after the completion of the dropwise addition, washing, and drying to give the Prussian white-based sodium-ion positive electrode material with a low water content.

Further, the stirring speed is 500-1000 rpm/min.

Further, the period of the aging reaction is 2 h.

Further, the molar ratio of Na₄Fe(CN)₆·10H₂O to the ethylenediaminetetraacetic acid manganese sodium salt is 1:(1-1.05).

Further, the acid is ascorbic acid, sulfuric acid, hydrochloric acid, nitric acid, acetic acid, or citric acid.

The present disclosure further provides a large single-crystal Prussian white-based sodium-ion positive electrode material of formula NaₓMn[Fe(CN)₆]_{y} acquired by the method described above, wherein 1.90≤x<2.00, and 0.90≤y<1.

Further, the large single-crystal Prussian white-based sodium-ion positive electrode material has a particle size D₅₀ of 2-6 μm.

Further, the large single-crystal Prussian white-based sodium-ion positive electrode material has a specific surface area of 7.5-9.5 m²/g.

Further, the large single-crystal Prussian white-based sodium-ion positive electrode material has a water content of less than 10%.

Further, the large single-crystal Prussian white-based sodium-ion positive electrode material has a Na:Mn ratio of (1.90-2.00):1.

The present disclosure is further intended to provide a positive electrode plate comprising: a positive electrode current collector, and a positive electrode active material comprising the large single-crystal Prussian white-based sodium-ion positive electrode material described above.

The present disclosure is further intended to provide a battery comprising the positive electrode plate described above.

The present disclosure is further intended to provide an electric device comprising the battery for powering.

According to the above technical solution, the present disclosure has the following advantages: By using an acidic cation dissociation method, a Prussian white-based sodium-ion positive electrode material with a low water content is synthesized at room temperature, avoiding the production of toxic gases. Furthermore, Na and the manganese source are mixed in a liquid phase to prepare a mixed solution before the reaction, allowing more uniform precipitation of Na and Mn. As a result, the synthesized positive electrode material features large primary particles, good thermal stability, a low water content, and a high capacity.

### BRIEF DESCRIPTION OF THE DRAWING

The FIGURE is a SEM image of the large single-crystal Prussian white-based sodium-ion positive electrode material according to the present disclosure.

### DETAILED DESCRIPTION

To better understand the technical solutions of the examples of the present application, the following detailed description is provided in combination with some preferred examples.

In the Specification, amounts, ratios, and other numerical values are sometimes presented herein in ranges. It will be appreciated that such ranges are used for convenience and brevity, and should be flexibly interpreted to include not only the values explicitly specified as the limits of the ranges, but also all the individual values or sub-ranges encompassed within those ranges as if each value and sub-range is explicitly specified.

The large single-crystal Prussian white-based sodium-ion positive electrode material provided by the present application has the chemical general formula NaₓMn[Fe(CN)₆]_{y}, wherein 1.90≤x<2.00, and 0.90≤y<1. The synthesis method comprises:
(1) mixing and dissolving Na₄Fe(CN)₆·10H₂O and ethylenediaminetetraacetic acid manganese sodium salt to prepare a first solution A; and
(2) dropwise adding a diluted acid, as a second solution B, into the first solution A, performing an aging reaction after the completion of the dropwise addition, washing, and drying to give the Prussian white-based sodium-ion positive electrode material with a low water content.

The method for preparing the Prussian white-based sodium-ion positive electrode material provided by the examples of the present application enables the synthesis at room temperature and more uniform precipitation by preparing Na and a manganese source into a mixed solution.

The acid used in the method is ascorbic acid, sulfuric acid, hydrochloric acid, nitric acid, acetic acid, or citric acid.

According to some examples of the present application, the large single-crystal Prussian white-based sodium-ion positive electrode material described above has a particle size D₅₀ of 2-6 μm, a water content of less than 10%, a specific surface area of 7.5-9.5 m²/g, and a Na:Mn ratio of (1.90-2.00):1. According to some examples of the present application, the stirring speed is 500-1000 rpm/min.

According to some examples of the present application, the period of the aging reaction is 2 h, so as to promote crystal growth.

According to some examples of the present application, the compound can be used as a positive electrode material for a sodium-ion battery. For example, the above compound is added to N-methylpyrrolidone (NMP) along with ketjen black and a binder polyvinylidene fluoride (PVDF) in a weight ratio of 86:7:7 (the weight ratio of the compound to NMP is 3:1). The mixture is uniformly mixed by stirring to give a uniform slurry to prepare a positive electrode material (or a positive electrode active material). The slurry is applied to an aluminum foil current collector, dried, and compressed to give a positive electrode plate, which may constitute an electrode assembly with a negative electrode plate.

The present application further provides a battery, specifically a sodium-ion battery, comprising the electrode assembly. The sodium-ion battery may be used in the fields of digital products, electric vehicles, or energy storage.

For example, a sodium-ion secondary battery is typically composed of an electrode assembly, an electrolyte, and a separator. Specifically, the electrode assembly may comprise a positive electrode plate and a negative electrode plate, as described above. The positive electrode plate may be made from materials including a positive electrode current collector, a positive electrode active material applied to the positive electrode current collector, a conventional binder, a conventional conductive additive, and the like. The positive electrode active material may comprise the compound disclosed in the present application. The negative electrode plate may be made from materials including a current collector, a conventional negative electrode active material applied to the current collector, a conventional binder, a conventional conductive additive, and the like. The separator is a polypropylene (PP)/polyethylene (PE) film conventionally used in the art, which serves to separate the positive electrode and negative electrode from each other.

Some other examples of the present application further provide an electric device comprising the battery for powering. The electric device may include a digital product, an electric vehicle, an energy storage apparatus, and the like.

The specific examples below are provided to illustrate the large single-crystal Prussian white-based sodium-ion positive electrode material and the method for preparing same according to the present application. The reagents and devices not described in the present application are all contents that can be conventionally confirmed by those of ordinary skill in the art.

The reagents used in the examples below are shown in Table 1-1.

TABLE 1-1
Information on chemical reagents used in examples of the present application

| Reagent | Grade | Purity | Manufacturer |
|---|---|---|---|
| Na₄Fe(CN)₆•10H₂O | Chemically | 99.5 wt % | XuanchengJingrui New |
| | pure | | Materials, Co., Ltd., Anhui |
| Ethylenediaminetetraacetic | Chemically | 99.5 wt % | XuanchengJingrui New |
| acid manganese sodium | pure | | Materials, Co., Ltd., Anhui |
| salt | | | |
| Ascorbic acid | Chemically | 99.5 wt % | XuanchengJingrui New |
| | pure | | Materials, Co., Ltd., Anhui |
| Sulfuric acid | Chemically | 99.5 wt % | XuanchengJingrui New |
| | pure | | Materials, Co., Ltd., Anhui |
| Hydrochloric acid | Chemically | 99.5 wt % | XuanchengJingrui New |
| | pure | | Materials, Co., Ltd., Anhui |
| Nitric acid | Chemically | 99.5 wt % | XuanchengJingrui New |
| | pure | | Materials, Co., Ltd., Anhui |
| Acetic acid | Chemically | 99.5 wt % | XuanchengJingrui New |
| | pure | | Materials, Co., Ltd., Anhui |
| Citric acid | Chemically | 99.5 wt % | XuanchengJingrui New |
| | pure | | Materials, Co., Ltd., Anhui |

The devices and analytical methods used in the following examples are as follows:

The ball mill was the SHQM dual-planetary ball mill from Lianyungang Chunlong Experimental Instrument Co., Ltd.

In the present application, the specific surface area was detected and analyzed using a surface area and porosity system (TriStar II 3020 from Micromeritics, USA).

The water content was measured on a synchronous differential thermal analyzer, with an upper test temperature limit of 500° C. and a ramping rate of 10° C./min. The percentage weight loss was taken as the water content.

The element content was determined as follows: 0.2000 g of the sample (rounded to 0.0001 g) was exactly taken and placed into a clean 100 mL glass beaker. 10 mL of aqua regia solution (1:1) was added into the beaker (a parallel blank group was set), and the beaker was covered with a watch glass and heated on an electric heater until the solvent was nearly depleted before stopping the heating. The beaker was then removed and cooled to room temperature. The watch glass and the side wall of the beaker were washed with deionized water at least thrice. The mixture was transferred into a 50 mL volumetric flask and diluted with deionized water to the mark. The mixture was well mixed by shaking. 1 mL of the sample was transferred into a 100 mL volumetric flask and diluted to the mark. The mixture was well mixed by shaking. The above solution was tested on an inductively coupled plasma emission spectrometer (Thermo Fisher Scientific Co., Ltd., USA/icap7400) with reference to YS/T 1006.2-2014, Part I.

The average particle size was determined using an MS3000 laser particle analyzer, with the procedures as follows:

A proper amount of sample was taken and added into a 100 ml beaker. First, the inner wall of the beaker was rinsed using a wash bottle, and then the sample adhering to the bottom of the beaker was rinsed using the wash bottle, with the amount of pure water added into the beaker controlled at 20-30 mL. The mixture was ultrasonicated for 5 min (stirring for 10 s before, during, and after the ultrasonication, with a stirring speed of about 2 r/s). 100±10 mL of pure water was added into a sample injector of the MS3000 laser particle analyzer; the rotating speed was adjusted to 3000 r/min before clicking on the start. The analyzer automatically completed procedures such as optical alignment, background measurement, and the like, until the system prompted further operations. The ultrasonicated sample was transferred into a stirring tank, and then the beaker was rinsed with a wash bottle to ensure complete transfer of the sample. Once the sample was fully added, the software automatically began the measurement. After the measurement was complete, the data were automatically saved.

The specific examples are as follows.

### Example 1

0.1 mol of Na₄Fe(CN)₆·10H₂O and 0.105 mol of ethylenediaminetetraacetic acid manganese sodium salt were dissolved in 1 L of distilled water to give a mixed solution A. 2 mol of ascorbic acid was dissolved in 1 L of distilled water to give a solution B. The solution B was added dropwise and slowly into the solution A over 1 h while stirring at 500 rpm/min. The mixture was stirred for 2 h after the completion of the dropwise addition for aging. The white precipitate was separated by 3 filtrations and washing, and dried at 150° C. for 10 h to give Prussian white material 1. The material was subjected to particle size, specific surface area, Tg, and battery tests. The data are shown in Table 1.

### Example 2

0.1 mol of Na₄Fe(CN)₆·10H₂O and 0.1 mol of ethylenediaminetetraacetic acid manganese sodium salt were dissolved in 1 L of distilled water to give a mixed solution A. 2 mol of sulfuric acid was dissolved in 1 L of distilled water to give a solution B. The solution B was added dropwise and slowly into the solution A over 1 h while stirring at 500 rpm/min. The mixture was stirred for 2 h after the completion of the dropwise addition for aging. The white precipitate was separated by 3 filtrations and washing, and dried at 150° C. for 10 h to give Prussian white material 2. The material was subjected to particle size, specific surface area, Tg, and battery tests. The data are shown in Table 1.

### Example 3

0.1 mol of Na₄Fe(CN)₆·10H₂O and 0.105 mol of ethylenediaminetetraacetic acid manganese sodium salt were dissolved in 1 L of distilled water to give a mixed solution A. 2 mol of hydrochloric acid was dissolved in 1 L of distilled water to give a solution B. The solution B was added dropwise and slowly into the solution A over 1 h while stirring at 1000 rpm/min. The mixture was stirred for 2 h after the completion of the dropwise addition for aging. The white precipitate was separated by 3 filtrations and washing, and dried at 150° C. for 10 h to give Prussian white material 3. The material was subjected to particle size, specific surface area, Tg, and battery tests. The data are shown in Table 1.

### Example 4

0.1 mol of Na₄Fe(CN)₆·10H₂O and 0.1 mol of ethylenediaminetetraacetic acid manganese sodium salt were dissolved in 1 L of distilled water to give a mixed solution A. 2 mol of nitric acid was dissolved in 1 L of distilled water to give a solution B. The solution B was added dropwise and slowly into the solution A over 1 h while stirring at 800 rpm/min. The mixture was stirred for 2 h after the completion of the dropwise addition for aging. The white precipitate was separated by 3 filtrations and washing, and dried at 150° C. for 10 h to give Prussian white material 4. The material was subjected to particle size, specific surface area, Tg, and battery tests. The data are shown in Table 1.

### Example 5

0.1 mol of Na₄Fe(CN)₆·10H₂O and 0.102 mol of ethylenediaminetetraacetic acid manganese sodium salt were dissolved in 1 L of distilled water to give a mixed solution A. 2 mol of acetic acid was dissolved in 1 L of distilled water to give a solution B. The solution B was added dropwise and slowly into the solution A over 1 h while stirring at 800 rpm/min. The mixture was stirred for 2 h after the completion of the dropwise addition for aging. The white precipitate was separated by 3 filtrations and washing, and dried at 150° C. for 10 h to give Prussian white material 5. The material was subjected to particle size, specific surface area, Tg, and battery tests. The data are shown in Table 1.

### Example 6

0.1 mol of Na₄Fe(CN)₆·10H₂O and 0.1 mol of ethylenediaminetetraacetic acid manganese sodium salt were dissolved in 1 L of distilled water to give a mixed solution A. 2 mol of citric acid was dissolved in 1 L of distilled water to give a solution B. The solution B was added dropwise and slowly into the solution A over 1 h while stirring at 800 rpm/min. The mixture was stirred for 2 h after the completion of the dropwise addition for aging. The white precipitate was separated by 3 filtrations and washing, and dried at 150° C. for 10 h to give Prussian white material 6. The material was subjected to particle size, specific surface area, Tg, and battery tests. The data are shown in Table 1.

TABLE 1
Characterization of compounds acquired in examples

| | Specific | Particle | Tg | | |
|---|---|---|---|---|---|
| | surface | size | Water | | Capacity |
| | area | D50 | content | ICP | 4.0 V |
| Compound | (m²/g) | (μm) | (%) | Na:Mn | 0.1 C(mAh/g) |
| 1 | 8.04 | 3.66 | 8.3 | 1.98:1 | 147 |
| 2 | 9.26 | 3.42 | 7.9 | 1.95:1 | 145 |
| 3 | 8.74 | 3.97 | 8.2 | 1.99:1 | 142 |
| 4 | 8.83 | 3.69 | 6.8 | 1.92:1 | 143 |
| 5 | 8.63 | 3.42 | 7.2 | 1.95:1 | 146 |
| 6 | 8.98 | 3.89 | 8.2 | 1.91:1 | 142 |

As shown in Table 1, the single-crystal positive electrode materials prepared by the foregoing example of the present application had a water content of less than 10%, a specific surface area of 7.5-9.5 m²/g, a particle size of 2.0-6.0 μm (suggesting large primary single-crystal particles), a Na:Mn ratio of (1.90-2.00):1, and a maximum specific capacity of 147 mAh/g.

As shown in Table 1, large primary single-crystal particles can be synthesized by the method of the present disclosure according to the examples. Compared to other methods, the synthesis is conducted at room temperature according to the present disclosure, and Na and the manganese source are mixed uniformly in the solution, resulting in more uniform precipitation of Na and Mn.

1. A method for preparing a large single-crystal Prussian white-based sodium-ion positive electrode material, comprising:
step 1, mixing and dissolving Na₄Fe(CN)₆·10H₂O and ethylenediaminetetraacetic acid manganese sodium salt to prepare a first solution A, the molar ratio of Na₄Fe(CN)₆·10H₂O to the ethylenediaminetetraacetic acid manganese sodium salt being 1:(1-1.05); and
step 2, dropwise and slowly adding an acid at a concentration of 2 mol/L, as a second solution B, into the first solution A while stirring for 1 h, with a stirring speed of 500-1000 rpm/min; performing an aging reaction for 2 h after the completion of the dropwise addition, washing, and drying to give the Prussian white-based sodium-ion positive electrode material, wherein
the Prussian white-based sodium-ion positive electrode material has a chemical general formula of NaₓMn[Fe(CN)₆]_{y}, 1.90≤x<2.00, and 0.90≤y<1; the Prussian white-based sodium-ion positive electrode material has a water content of less than 10%.

2. The method according to claim 1, wherein the acid is ascorbic acid, sulfuric acid, hydrochloric acid, nitric acid, acetic acid, or citric acid.

3. The method according to claim 1, wherein the large single-crystal Prussian white-based sodium-ion positive electrode material has a particle size D₅₀ of 2-6 μm.

4. The method according to claim 1, wherein the large single-crystal Prussian white-based sodium-ion positive electrode material has a specific surface area of 7.5-9.5 m²/g.

5. A positive electrode plate, comprising a positive electrode current collector and a positive electrode active material, wherein the positive electrode active material comprises the large single-crystal Prussian white-based sodium-ion positive electrode material according to claim 1.

6. A battery, comprising the positive electrode plate according to claim 5.

7. An electrical device, comprising the battery according to claim 6, and the battery is used to provide electrical energy.
